(19) United States
(12) Patent Application Publication
(10) Pub. No.: US 2025/0318151 A1
(43) Pub. Date: Oct. 9, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chin-Hung Chen, Tainan City (TW); Ssu-I Fu, Kaohsiung City (TW); Po-Kuang Hsieh, Kaohsiung City (TW); Chun-Ya Chiu, Tainan City (TW); Yu-Hsiang Lin, New Taipei City (TW)

(73) Assignee: UNITED MICROELECTRONICS CORP., Hsin-Chu City (TW)

(21) Appl. No.: 18/661,706

(22) Filed: May 12, 2024

(30) Foreign Application Priority Data
Apr. 3, 2024 (TW) 113112726

(51) Int. Cl. H01L 27/08

(52) U.S. Cl. CPC H10D 1/042; H10D 1/716; H10D 84/212

(57) ABSTRACT

A semiconductor device includes a substrate, a first trench, a second trench and a capacitor structure. The substrate defines a first region. The first trench is disposed in the first region of the substrate and extends along a first direction. The first trench includes a first trench portion, a first partition portion and a second trench portion sequentially arranged along the first direction. The second trench is disposed in the first region of the substrate and extends along the first direction. The second trench includes a third trench portion, a second partition portion and a fourth trench portion sequentially arranged along the first direction. The first partition portion and the second partition portion are misaligned with each other in a second direction perpendicular to the first direction. The capacitor structure is disposed in the first trench and the second trench and on a top surface of the substrate.

### BACKGROUND OF THE INVENTION

### 1. Field of the Invention

The present disclosure relates to the field of semiconductor devices, and more particularly, to a semiconductor device including a deep trench capacitor structure and a method for fabricating the same.

### 2. Description of the Prior Art

Due to capacitor structures capable of storing charges, the capacitor structures are widely applied to components of semiconductor devices such as memories. The conventional capacitor structures are planar capacitor structures. However, with the development of artificial intelligence (AI) and high performance computing (HPC), the desired capacitance value provided by the capacitor structure is gradually In increased. order to simultaneously satisfy the needs of AI and HPC and the trend of miniaturization of electronic components, deep trench capacitor structures are provided. However, the desired capacitance value provided by the capacitor structure is increasing, and the depth of the trenches are required to be deepened. As a result, the stress is increased, and the yield is affected thereby.

### SUMMARY OF THE INVENTION

According to one aspect of the present disclosure, a semiconductor device includes a substrate, a first trench, a second trench and a capacitor structure. The substrate defines a first region. The first trench is disposed in the first region of the substrate and extends along a first direction. The first trench includes a first trench portion, a first partition portion and a second trench portion sequentially arranged along the first direction. The second trench is disposed in the first region of the substrate and extends along the first direction. The second trench includes a third trench portion, a second partition portion and a fourth trench portion sequentially arranged along the first direction. The first partition portion and the second partition portion are misaligned with each other in a second direction perpendicular to the first direction. The capacitor structure is disposed in the first trench and the second trench and on a top surface of the substrate.

According to another aspect of the present disclosure, a method for fabricating a semiconductor device includes steps as follows. A substrate defining a first region is provided. A first trench is formed in the first region of the substrate and the first trench extends along a first direction. The first trench includes a first trench portion, a first partition portion and a second trench portion sequentially arranged along the first direction. A second trench is formed in the first region of the substrate and the second trench extends along the first direction. The second trench includes a third trench portion, a second partition portion and a fourth trench portion sequentially arranged along the first direction, and the first partition portion and the second partition portion are misaligned with each other in a second direction perpendicular to the first direction. A capacitor structure is formed in the first trench and the second trench and on a top surface of the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view showing a step of a method for fabricating a semiconductor device according to an embodiment of the present disclosure.

FIG. 2 is a schematic cross-sectional view of the semiconductor device in FIG. 1 taken along line A-A′.

FIG. 3 is a schematic view showing a step of a method for fabricating a semiconductor device according to an embodiment of the present disclosure.

FIG. 4 is a schematic cross-sectional view of the semiconductor device in FIG. 3 taken along line A-A′.

FIG. 5 is a schematic view showing a step of a method for fabricating a semiconductor device according to an embodiment of the present disclosure.

FIG. 6 is a schematic cross-sectional view of the semiconductor device in FIG. 5 taken along line A-A′.

FIG. 7 is a schematic view showing a step of a method for fabricating a semiconductor device according to an embodiment of the present disclosure.

FIG. 8 is a schematic cross-sectional view of the semiconductor device in FIG. 7 taken along line A-A′.

FIG. 9 is a schematic view showing a step of a method for fabricating a semiconductor device according to an embodiment of the present disclosure.

FIG. 10 is a schematic cross-sectional view of the semiconductor device in FIG. 9 taken along line A-A′.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

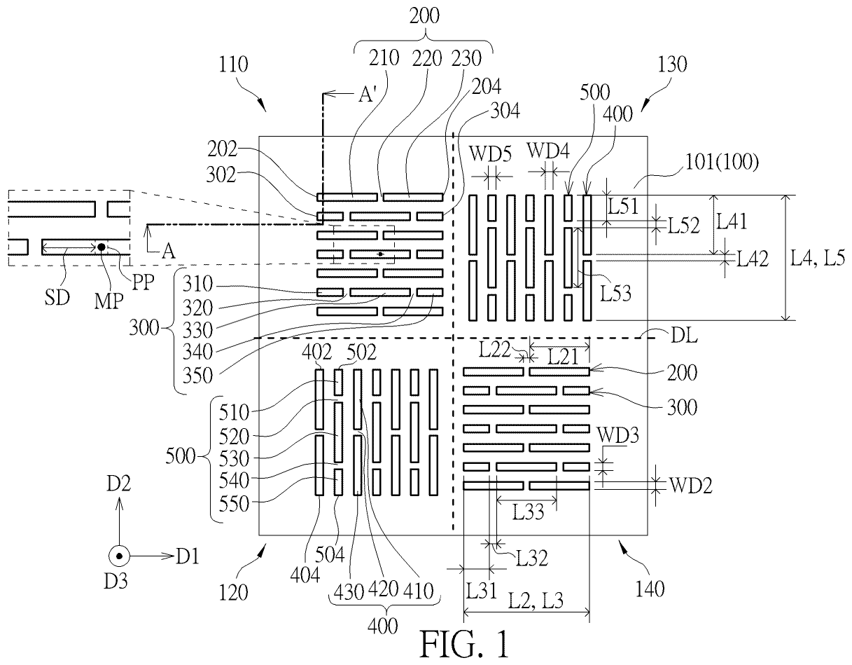

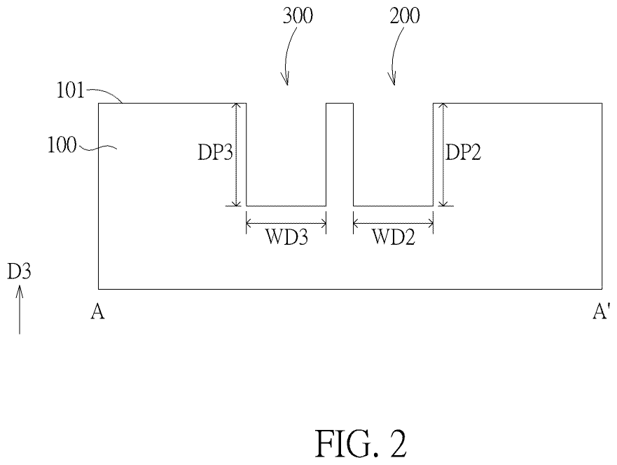

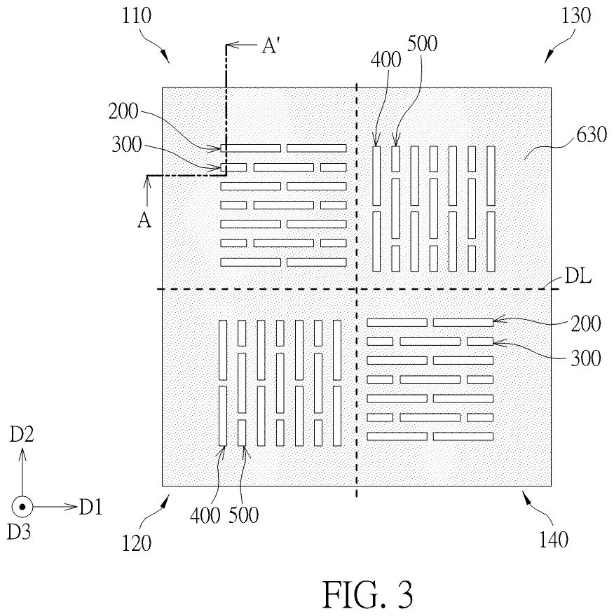

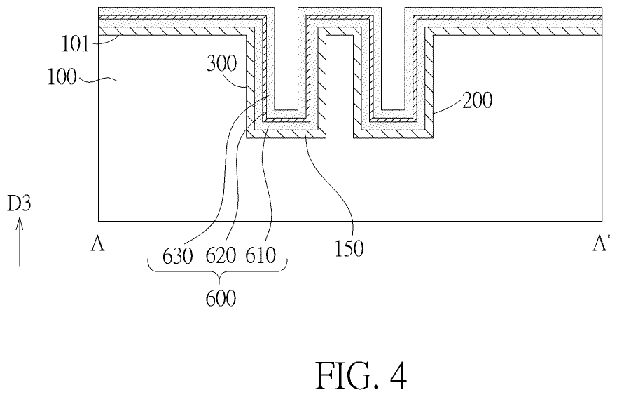

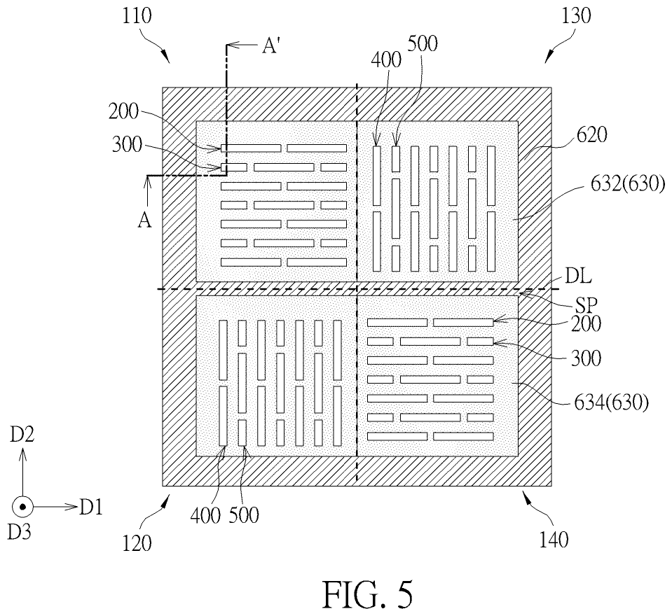

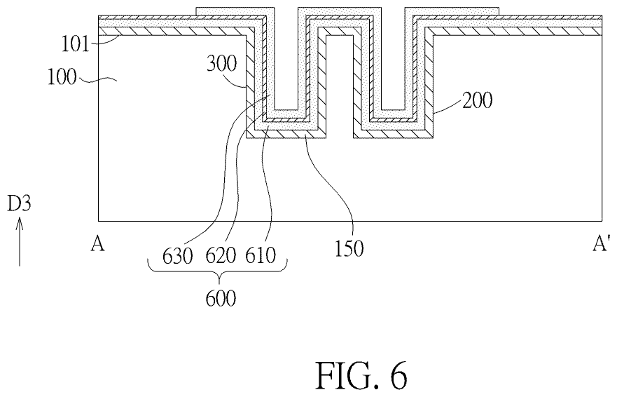

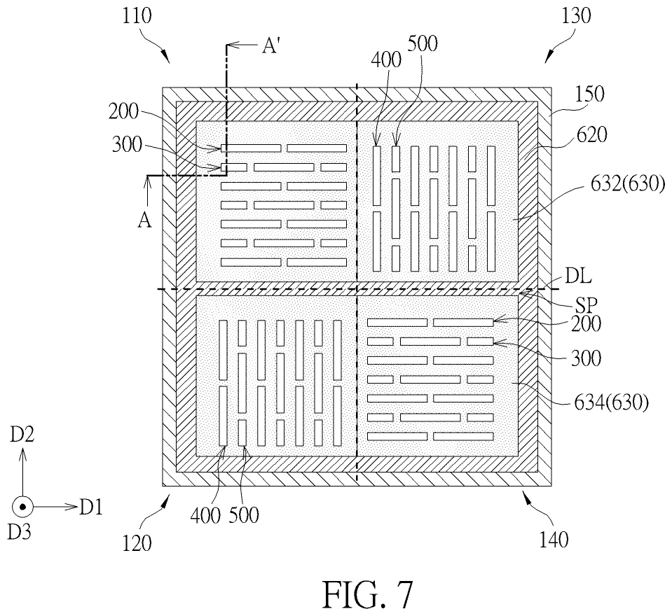

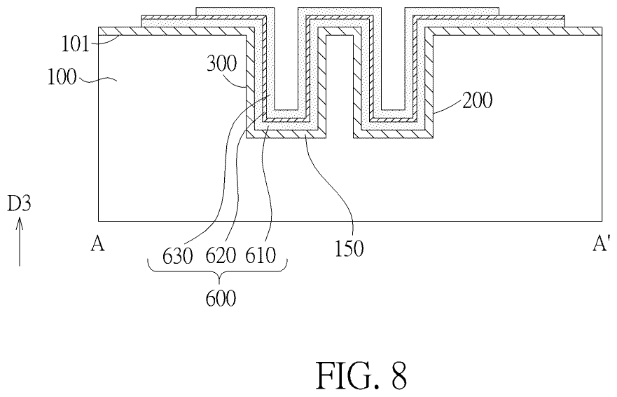

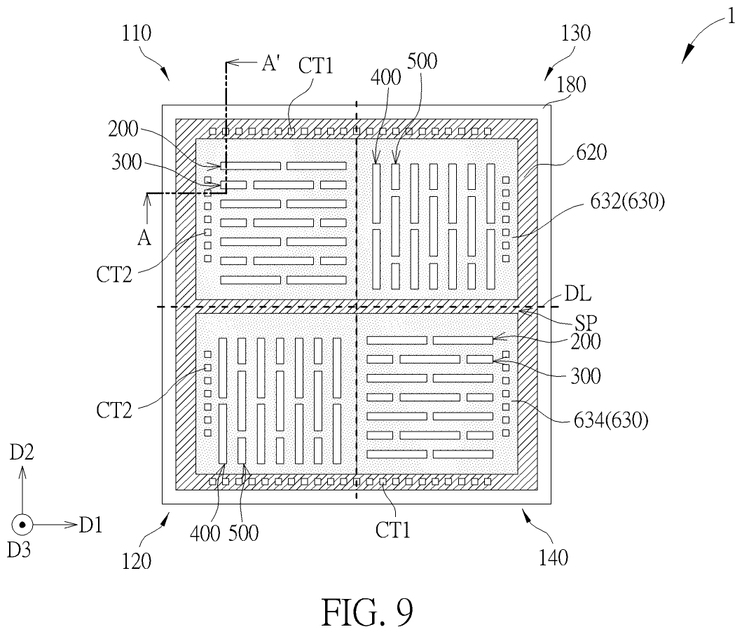

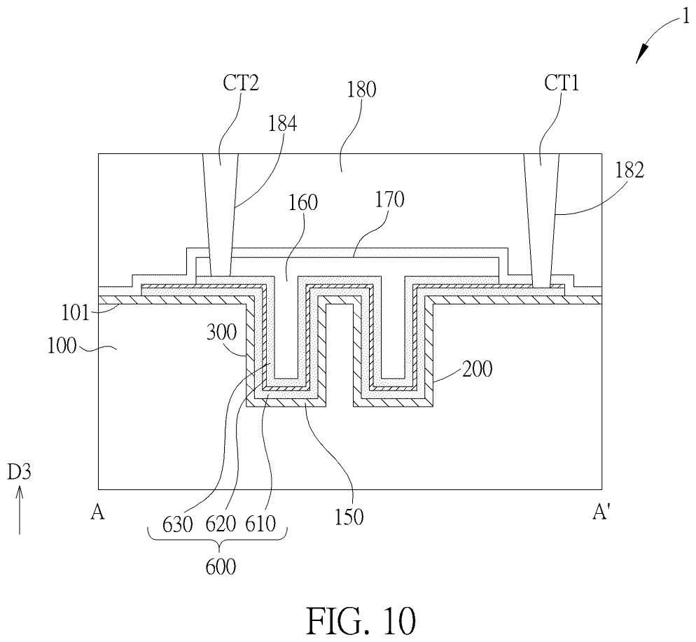

Please refer to FIG. 1 to FIG. 10. FIG. 1, FIG. 3, FIG. 5, FIG. 7 and FIG. 9 are schematic views showing steps of a method for fabricating a semiconductor device according to an embodiment of the present disclosure. FIG. 2, FIG. 4, FIG. 6, FIG. 8 and FIG. 10 are respectively schematic cross-sectional views of the semiconductor devices in FIG. 1, FIG. 3, FIG. 5, FIG. 7 and FIG. 9 taken along line A-A′.

In FIG. 1 and FIG. 2, a substrate 100 is firstly provided. The substrate 100 may be a silicon substrate, an epitaxial silicon substrate, a silicon carbide substrate or a silicon on insulator (SOI) substrate. The substrate 100 is defined with a first region 110, and may be optionally defined with a second region 120, a third region 130, and a fourth region 140. The boundaries of the first region 110, the second region 120, the third region 130 and the fourth region 140 may be the dotted lines DL shown in FIG. 1. The first region 110 and the second region 120 are disposed adjacent to each other in the second direction D2. The third region 130 and the fourth region 140 are disposed adjacent to each other in the second direction D2. The first region 110 and the third region 130 are disposed adjacent to each other in the first direction D1. The second region 120 and fourth region 140 are disposed adjacent to each other in the first direction D1. The second direction D2 is perpendicular to the first direction D1.

Next, semiconductor processes, such as photolithography and etching process, may be performed to form a plurality of first trenches 200 and a plurality of second trenches 300 in the first region 110 and the fourth region 140, and to form a plurality of third trenches 400 and a plurality of fourth trenches 500 in the second region 120 and the third region 130.

Each of the first trenches 200 extends along the first direction D1, and includes a trench portion 210, a partition portion 220 and a trench portion 230 sequentially arranged along the first direction D1. Each of the second trenches 300 includes a trench portion 310, a partition portion 320, a trench portion 330, a partition portion 340 and a trench portion 350 sequentially arranged along the first direction D1. That is, the extending directions of the first trenches 200 and the second trenches 300 are parallel to each other, and the first trenches 200 and the second trenches 300 are arranged along the second direction D2. The partition portion 220 of the first trench 200 is respectively misaligned with the partition portion 320 and the partition portion 340 of the second trench 300 in the second direction D2.

In the present disclosure, two elements being misaligned with each other in a direction refers that the two elements are not completely aligned (such as partially misaligned) with each other in the direction, or refers that the two elements are completely misaligned with each other in the direction. For example, there is a spaced distance SD between the projection PP of the partition portion 220 of the first trench 200 on the second trench 300 along the second direction D2 and the partition portion 320 of the second trench 300, so that the partition portion 220 of the first trench 200 is completely misaligned with the partition portion 320 of the second trench 300. In other embodiments, the projection PP of the partition portion 220 of the first trench 200 on the second trench 300 along the second direction D2 may partially overlap the partition portion 320 of the second trench 300, so that the partition portion 220 of the first trench 200 is not completely aligned with the partition portion 320 of the second trench 300.

Each of the third trenches 400 extends along the second direction D2, and includes a trench portion 410, a partition portion 420 and a trench portion 430 sequentially arranged along the second direction D2. Each of the fourth trenches 500 extends along the second direction D2, and includes a trench portion 510, a partition portion 520, a trench portion 530, a partition portion 540 and a trench portion 550 sequentially arranged along the second direction D2. The extending directions of the third trenches 400 and the fourth trenches 500 are parallel to each other, and the third trenches 400 and the fourth trenches 500 are arranged along the first direction D1. The partition portion 420 of the third trench 400 is respectively misaligned with the partition portion 520 and the partition portion 540 of the fourth trench 500 in the first direction D1.

In the conventional trenches without the partition portions, compressive stress tends to be generated in the direction perpendicular to the extending direction of the trenches, which may cause problems such as the fracture of the substrate 100. As a result, the yield of the semiconductor device is decreased. In the present disclosure, the trenches are divided into at least two trench portions by the partition portions, and the partition portions of two adjacent trenches are misaligned with each other in the direction perpendicular to the trench length direction, so that the compressive stress may be reduced. Thereby, it is beneficial to increase the depths of the trenches. On the one hand, the capacitor structure 600 formed later can provide a larger capacitance value. On the other hand, the problem that the yield is reduced due to the excessive compressive stress caused by the increase of the depths of the trenches may be improved. Taking the first region 110 as an example, the extending direction of each of the first trenches 200 and the second trenches 300 is the first direction D1. With the first trench 200 being disposed with the partition portion 220 and the second trench 300 being disposed with the partition portions 320 and 340, the compressive stress from the upper portion toward the inner portion of the first region 110 along the second direction D2 and the compressive stress from the lower portion of the first region 110 toward the inner portion of the first region 110 along the second direction D2 can be reduced.

In FIG. 1, in the first region 110, the number of the first trenches 200 is four, the number of the second trenches 300 is three, and each of the first trenches 200 and each of the second trenches 300 are alternately disposed along the second direction D2. In the second direction D2, each of the first trenches 200 is directly adjacent to at least one of the second trenches 300. The aforementioned “each of the first trenches 200 is directly adjacent to at least one of the second trenches 300” refers that there are no other trenches disposed between the first trench 200 and the second trench 300 which are directly adjacent to each other.

The two ends of the first trench 200 in the first direction D1 (such as the left end 202 and the right end 204) are respectively aligned with the two ends of the second trench 300 in the first direction D1 (such as the left end 302 and the right end 304) along the second direction D2. That is, in the first direction D1, the length L2 of the first trench 200 is equal to the length L3 of the second trench 300.

In the present disclosure, the extending direction of the trench may refer to the trench length direction, i.e., the extending direction of the length of the trench. Taking the first trench 200 as an example, in the top view of the semiconductor device, the first trench 200 has a rectangular shape. The length of the long side of the rectangular shape is defined as the length L2 of the first trench 200, and the length of the short side of the rectangular shape is defined as the width WD2 of the first trench 200. The trench length direction of the first trench 200 is the extending direction of the length L2, herein, the first direction D1. Similarly, the trench length direction of the second trench 300 is the extending direction of the length L3, herein, the first direction D1. The trench length directions of the third trench 400 and the fourth trench 500 are respectively the extending directions of the lengths L4 and L5, herein, the second direction D2.

The first trench 200 includes two trench portions 210 and 230 and a partition portion 220. For example, in the photolithography process to form the first trench 200, the positions of the trench portions 210, 230 and the partition portion 220 may be defined by a photomask. Afterward, a portion of the substrate 100 is removed by an etching process to form the trench portions 210 and 230, and the portion of the substrate 100 between the trench portions 210 and 230 forms the partition portion 220. In the first direction D1, the lengths L21 of the trench portions 210 and 230 are th same, and the trench portions 210 and 230 are symmetrically disposed at two sides of the partition portion 220. The lengths L21 of the trench portions 210 and 230 are greater than the length L22 of the partition portion 220. However, the present disclosure is not limited thereto. For example, in other embodiments, the lengths L21 of the trench portions 210 and 230 may be different and the trench portions 210 and 230 may be asymmetrically disposed at two sides of the partition portion 220.

In the second direction D2, the first trench 200 has a width WD2, and the width WD2 is substantially fixed along the first direction D1. That is, the widths (not labeled) of the trench portions 210 and 230 and the partition portion 220 in the second direction D2 are the same.

The second trench 300 includes three trench portions 310, 330 and 350 and two partition portions 320 and 340. In the first direction D1, the lengths L31 of the trench portions 310 and 350 are the same, and the trench portions 310 and 350 are symmetrically disposed at two sides of the trench portion 330. The lengths L32 of the partition portions 320 and 340 are the same, and the partition portions 320 and 340 are symmetrically disposed at two sides of the trench portion 330. The length L33 of the trench portion 330 located at the middle is greater than the lengths L31 of the trench portions 310 and 350 at the two sides, and the length L33 and the length L31 may satisfy the following condition: L33≥2×L31. In addition, in the first direction D1, the lengths L31 of the trench portions 310 and 350 and the length L33 of the trench portion 330 are all greater than the lengths L32 of the partition portions 320 and 340. However, the present disclosure is not limited thereto. For example, in other embodiments, the lengths L31 of the trench portions 310 and 350 may be different and the trench portions 310 and 350 may be asymmetrically disposed at two sides of the trench portion 330. In the second direction D2, the second trench 300 has a width WD3, and the width WD3 is substantially fixed along the first direction D1. That is, the widths (not labeled) of the trench portions 310, 330 and 350 and the partition portions 320 and 340 in the second direction D2 are the same.

In FIG. 2, the first trench 200 may have a depth DP2 in the vertical direction D3, and the first trench 200 may have the width WD2 in the second direction D2. The ratio of the depth DP2 to the width WD2 may be 24 to 36. The depth DP2 may be 6 μm to 9 μm. The width WD2 may be 0.25 μm to 0.32 μm. The second trench 300 may have a depth DP3 in the vertical direction D3, and the second trench 300 may have the width WD3 in the second direction D2. The ratio of the depth DP3 to the width WD3 may be 24 to 36. The depth DP3 may be 6 μm to 9 μm. The width WD3 may be 0.25 μm to 0.32 μm. Thereby, each of the first trench 200 and the second trench 300 can have a larger aspect ratio (i.e., the depth-to-width ratio), which is beneficial to improve the capacitance value of the capacitor structure 600 formed later. The aforementioned vertical direction D3 may be, for example, parallel to the normal direction (not shown) of the top surface 101 of the substrate 100), and perpendicular to the first direction D1 and the second direction D2. In this embodiment, the first trenches 200 and the second trenches 300 may be fabricated simultaneously. The width WD2 may be equal to the width WD3. The depth DP2 may be equal to the depth DP3. The aspect ratio of the first trench 200 and the aspect ratio of the second trench 300 may be the same. However, the present disclosure is not limited thereto. The first trenches 200 and the second trenches 300 can be fabricated separately according to actual needs. The width WD2 may be unequal to the width WD3. The depth DP2 may be unequal to the depth DP3. The aspect ratio of the first trench 200 may be unequal to the aspect ratio of the second trench 300.

In FIG. 1, there is a midpoint MP between the partition portion 320 and the partition portion 340 of the second trench 300, and the partition portion 220 of the first trench 200 may correspond to the midpoint MP along the second direction D2. The aforementioned “the partition portion 220 of the first trench 200 may correspond to the midpoint MP along the second direction D2” refers that the partition portion 220 of the first trench 200 has a projection PP on the second trench 300 along the second direction D2, and the midpoint MP is located within the projection PP. In some embodiments, the midpoint (not shown) of the partition portion 220 of the first trench 200 may be aligned with the midpoint MP along the second direction D2. The midpoint MP may be defined as a point located between the right side wall (not labeled) of the partition portion 320 and the left side wall (not labeled) of the partition portion 340, and a distance between the point and the right side wall of the partition portion 320 is equal to a distance between the point and the left side wall of the partition portion 340. In this embodiment, the midpoint MP may coincide with the center point (not shown) of the second trench 300, but not limited thereto.

In the second region 120, the number of the third trenches 400 is four, the number of fourth trenches 500 is three, and each of the third trenches 400 and each of the fourth trenches 500 are alternately disposed along the first direction D1. In the first direction D1, each of the third trenches 400 is directly adjacent to at least one of the fourth trenches 500. The aforementioned “each of the third trenches 400 is directly adjacent to at least one of the fourth trenches 500” refers that there are no other trenches disposed between the third trench 400 and the fourth trench 500 which are directly adjacent to each other.

The two ends of the third trench 400 in the second direction D2 (such as the upper end 402 and he lower end 404) are respectively aligned with the two ends of the fourth trench 500 in the second direction D2 (such as the upper end 502 and the lower end 504) along the first direction D1. That is, in the second direction D2, the length L4 of the third trench 400 is equal to the length L5 of the fourth trench 500.

The third trench 400 includes two trench portions 410 and 430 and a partition portion 420. In the second direction D2, the lengths L41 of the trench portions 410 and 430 are the same, and the trench portions 410 and 430 are symmetrically disposed at two sides of the partition portion 420. The lengths L41 of the trench portions 410 and 430 are greater than the length L42 of the partition portion 420. In the first direction D1, the third trench 400 has a width WD4, and the width WD4 is substantially fixed along the second direction D2. That is, the widths (not labeled) of the trench portions 410 and 430 and the partition portion 420 in the first direction D1 are the same.

The fourth trench 500 includes three trench portions 510, 530 and 550 and two partition portions 520 and 540. In the second direction D2, the lengths L51 of the trench portions 510 and 550 are the same, and the trench portions 510 and 550 are symmetrically disposed at two sides of the trench portion 530. The lengths L52 of the partition portions 520 and 540 are the same, and the partition portions 520 and 540 are symmetrically disposed at two sides of the trench portion 530. The length L53 of the trench portion 530 located at the middle is greater than the lengths L51 of the trench portions 510 and 550 located at the two sides, and the length L53 and the length L51 may satisfy the following condition: L53≥2×L51. In addition, the lengths L51 of the trench portions 510 and 550 and the length L53 of the trench portion 530 are all greater than the lengths L52 of the partition portions 520 and 540. In the first direction D1, the fourth trench 500 has a width WD5, and the width WD5 is substantially fixed along the second direction D2. That is, the widths (not labeled) of the trench portions 510, 530 and 550 and the partition portions 520 and 540 in the first direction D1 are the same.

The main difference between the second region 120 and the first region 110 is that the first trenches 200 and the second trenches 300 in the first region 110 are respectively replaced by the third trenches 400 and the fourth trenches 500 in the second region 120. The main difference between the third trench 400 and the first trench 200 is the extending direction, and the main difference between the fourth trench 500 and the second trench 300 is the extending direction. For other details about the third trench 400 and the fourth trench 500, reference may be made to the relevant descriptions of the first trench 200 and the second trench 300 above.

The number and the arrangement of the third trenches 400 and the fourth trenches 500 in the third region 130 are identical to that of the third trenches 400 and the fourth trenches 500 in the second region 120, and the number and the arrangement of the first trenches 200 and the second trenches 300 in the fourth region 140 are identical to that of the first trenches 200 and the second trenches 300 in the first region 110, which may refer to the relevant descriptions of the first region 110 and the second region 120 above.

In this embodiment, the number of the trenches in each of the regions is exemplary, and the number, the size and the arrangement of the trench portions and partition portions of each of the trenches are also exemplary, and all of which can be flexibly adjusted according to actual needs. For example, in the photolithography process of forming the trenches (such as the first trench 200 and the second trench 300), the number, the lengths, and the arrangement of the trench portions and the partition portions of each trench can be adjusted by adjusting the pattern of the photomask. As long as partition portions of two directly adjacent trenches are misaligned with each other in the direction perpendicular to the trench length direction, or trench portions of two directly adjacent trenches are misaligned with each other in the direction perpendicular to the trench length direction, the stress may be reduced.

Furthermore, in this embodiment, there are two different types of trenches in the same region (such as the first trench 200 and the second trench 300 in the first region 110), and the partition portions of the two different types of trenches (such as the partition portions 220, 320 and 340) are all misaligned with each other in the direction perpendicular to the trench length direction (for example, the partition portions 220 and 320 are misaligned with each other, and the partition portions 220 and 340 are misaligned with each other). Furthermore, the partition portions of the same type of trenches in the same region (such as the plurality of first trenches 200 in the first region 110) are all aligned with each other in the direction perpendicular to the trench length direction. However, in other embodiments, some of the partition portions of two different types of trenches in the same region may be aligned with other in the direction perpendicular to the trench length direction, while the other of the partition portions of the two different types of trenches in the same region may be misaligned with other in the direction perpendicular to the trench length direction. Alternatively, the partition portions of the same type of trenches in the same region may be misaligned with each other in the direction perpendicular to the trench length direction. For example, the left ends of the same type of trenches in the same region may be misaligned with each other so that the partition portions thereof are also misaligned with each other. As another example, the left ends of the plurality of trenches in the same region (of the same type or different types) are misaligned with each other to form an S shape, a wavy shape, or an oblique line shape in the top view of the semiconductor device. As another example, all the trenches in the same region may be different. That is, the types of trenches in the same region are not repeated.

Next, as shown in FIG. 3 and FIG. 4, a liner 150 may be optionally formed in the first trenches 200, the second trenches 300, the third trenches 400 and the fourth trenches 500 and on the top surface 101 of the substrate 100. The liner 150 conformally covers the inner surfaces (not labeled) of the first trenches 200, the second trenches 300, the third trenches 400 and the fourth trenches 500. A material of the liner 150 may include silicon oxide (SiOₓ).

Next, the capacitor structure 600 is formed in the first trenches 200, the second trenches 300, the third trenches 400 and the fourth trenches 500 and on the top surface 101 of the substrate 100, which may include steps as follows. First, the bottom electrode layer 610 is formed in the first trenches 200, the second trenches 300, the third trenches 400 and the fourth trenches 500 and on the top surface 101 of the substrate 100, in which the bottom electrode layer 610 conformally covers the inner surfaces of the first trenches 200, the second trenches 300, the third trenches 400 and the fourth trenches 500 and the top surface 101 of the substrate 100 through the liner 150. Next, an insulating layer 620 is formed on the bottom electrode layer 610, and a top electrode layer 630 is formed on the insulating layer 620. The materials of the bottom electrode layer 610 and the top electrode layer 630 may include conductive materials, such as copper (Cu), chromium (Cr), titanium (Ti), tungsten (W), gold (Au), aluminum (Al), indium (In), tin (Sn), nickel (Ni), platinum (Pt), silver (Ag) or alloys thereof, but not limited thereto. According to an embodiment of the present disclosure, the materials of the bottom electrode layer 610 and the top electrode layer 630 include titanium nitride (TiN). The material of the insulating layer 620 may include a high dielectric constant material. The insulating layer 620 may be a single-layer structure or a multi-layer structure. According to an embodiment of the present disclosure, the insulating layer 620 may be Zr0₂/Al₂O₃/Zro₂ (ZAZ).

Next, as shown in FIG. 5 and FIG. 6, the size of the top electrode layer 630 is defined. Semiconductor processes such as photolithography and etching processes may be performed to remove a portion of the top electrode layer 630 to expose a portion of the insulating layer 620. Specifically, the peripheral portion of the top electrode layer 630 located in the first region 110 to the fourth region 140 is removed, so that the top electrode layer 630 is electrically isolated from components (not shown) disposed outside the first region 110 to the fourth region 140. Moreover, the portion of the top electrode layer 630 located between the first region 110 and the third region 130 and the portion of the top electrode layer 630 located between the second region 120 and the fourth region 140 are removed to form a separation space SP, so that the remaining top electrode layer 630 is divided into a first sublayer 632 and a second sublayer 634. The first sublayer 632 is disposed in the first region 110 and the third region 130, the second sublayer 634 is disposed in the second region 120 and the fourth region 140, and the separation space SP is located between the first sublayer 632 and the second sublayer 634 and extends along the first direction D1. With the separation space SP, the stress of the top electrode layer 630 can be reduced, which can further improve the yield.

Next, as shown in FIG. 7 and FIG. 8, the size of the bottom electrode layer 610 is defined. Semiconductor processes such as photolithography and etching processes may be performed to remove the peripheral portions of the insulating layer 620 and the bottom electrode layer 610 located in the first region 110 to the fourth region 140 to expose a portion of the liner 150, so that the bottom electrode 610 is electrically isolated from the components (not shown) disposed outside the first region 110 to the fourth region 140.

Next, as shown in FIG. 9 and FIG. 10, a dielectric layer 160 is completely deposited on the substrate 100, and semiconductor processes such as photolithography and etching processes are performed to remove the portion of the dielectric layer 160 located outside the top electrode layer 630, and only the portion of the dielectric layer 160 located on the top electrode layer 630 is reserved. The dielectric layer 160 is filled into the first trenches 200, the second trenches 300, the third trenches 400 and the fourth trenches 500 and is located on the top electrode layer 630. Next, a contact etch stop layer (CESL) 170 is completely deposited on the substrate 100. The contact etch stop layer 170 is disposed on the dielectric layer 160, on the portion of the insulating layer 620 that is not covered by the dielectric layer 160 and the top electrode layer 630, and on the portion of the liner 150 that is not covered by the insulating layer 620 and the bottom electrode layer 610. Next, a dielectric layer 180 is completely deposited on the substrate 100 to cover the contact etch stop layer 170. The materials of the dielectric layers 160 and 180 may independently include oxides, such as silicon dioxide or tetraethoxysilane (TEOS), and the material of the contact etch stop layer 170 may include silicon nitride, but not limited thereto.

Next, a plug process is performed. First, semiconductor processes such as photolithography and etching process are performed to remove a portion of the dielectric layer 180, a portion of the contact etch stop layer 170 and a portion of the insulating layer 620 to form a plurality of holes 182 to expose the bottom electrode layer 610, and further semiconductor processes such as photolithography and etching process are performed to remove a portion of the dielectric layer 180, a portion of the contact etch stop layer 170 and a portion of the dielectric layer 160 to form a plurality of holes 184 to expose the top electrode layer 630. Next, a conductive material is filled into the holes 182 and 184, and a planarization process is performed to form a plurality of first contacts CT1 and a plurality of second contacts CT2 in the dielectric layer 180. The plurality of first contacts CT1 are arranged along the first direction D1 and are electrically connected to the bottom electrode layer 610. The plurality of second contacts CT2 are arranged along the second direction D2 and are electrically connected to the top electrode layer 630. Specifically, some of the plurality of second contacts CT2 are disposed on the first sublayer 632, and some of the plurality of second contacts CT2 are disposed on the second sublayer 634, and the second contacts CT2 disposed on the first sublayer 632 and the second contacts CT2 disposed on the second sublayer 634 can be electrically connected with each other through other metal interconnections (not shown). In other words, the first sublayer 632 and the second sublayer 634 are electrically connected with each other. The conductive materials of first contact CT1 and second contact CT2 may be the same or different, and may independently include a barrier layer (not shown) and a metal layer (not shown). The material of the barrier layer may include titanium (Ti), tantalum (Ta), titanium nitride (TiN), tantalum nitride (TaN), nitrogen (N) or a combination thereof. The material of the metal layer may include aluminum (Al), titanium (Ti), tantalum (Ta), tungsten (W), niobium (Ni), molybdenum (Mo), copper (Cu) or a combinations thereof, but not limited thereto. Thereby, the fabrication of the semiconductor device 1 is completed.

The aforementioned film layers, such as the bottom electrode layer 610, the insulating layer 620, the top electrode layer 630, the dielectric layer 160, the contact etch stop layer 170, the dielectric layer 180, the first contact CT1 and the second contact CT2, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

Please refer to FIG. 9 and FIG. 10. FIG. 9 is a schematic top view of the semiconductor device 1 according to an embodiment of the present disclosure, and FIG. 10 is a schematic cross-sectional view of the semiconductor device 1 in FIG. 9 taken along line A-A′. The semiconductor device 1 includes the substrate 100, the first trenches 200, the second trenches 300 and the capacitor structure 600. Please refer to FIG. 1 simultaneously. The substrate 100 defines a first region 110. The first trenches 200 are disposed in the first region 110 of the substrate 100 and extend along the first direction D1. Each of the first trenches 200 includes the trench portion 210, the partition portion 220 and the trench portion 230 sequentially arranged along the first direction D1. The second trenches 300 are disposed in the first region 110 of the substrate 100 and extend along the first direction D1. Each of the second trenches 300 includes the trench portion 310, the partition portion 320 and the trench portion 330 sequentially arranged along the first direction D1. The partition portion 220 and the partition portion 320 are misaligned with each other in the second direction D2. The second direction D2 is perpendicular to the first direction D1.

In FIG. 1 and FIG. 9, the second trench 300 may further include a trench portion 350 and a partition portion 340 disposed between the trench portion 330 and the trench portion 350, and the partition portion 220 and the partition portion 340 are misaligned with each other in the second direction D2. There is a midpoint MP between the partition portion 320 and the partition portion 340, and the partition portion 220 may correspond to the midpoint MP along the second direction D2. The number of first trenches 200 may be at least two, the number of second trenches 300 may be at least two, and each of the at least two of the first trenches 200 and each of the at least two of the second trenches 300 are alternatively disposed along the second direction D2.

The substrate 100 may optionally further define a second region 120, a third region 130 and a fourth region 140. The second region 120 is disposed adjacent to the first region 110 along the second direction D2. The third region 130 is disposed adjacent to the first region 110 along the first direction D1. The fourth region 140 is disposed adjacent to the second region 120 along the first direction D1. The semiconductor device 1 may optionally further includes the third trenches 400 and the fourth trenches 500 disposed in the second region 120 and the third region 130 of the substrate 100. The semiconductor device 1 may optionally further include other first trenches 200 and other second trenches 300 disposed in the fourth region 140 of the substrate 100. For the arrangement of the trenches in the second region 120, the third region 130 and the fourth region 140, reference may be made to the relevant description above.

The capacitor structure 600 includes, from bottom to top, the bottom electrode layer 610, the insulating layer 620 and the top electrode layer 630. The bottom electrode layer 610 is disposed in the first trenches 200, the second trenches 300, the third trenches 400 and the fourth trenches 500 and on the top surface 101 of the substrate 100. The insulating layer 620 is disposed on the bottom electrode layer 610. The top electrode layer 630 is disposed on the insulating layer 620. The top electrode layer 630 includes the first sublayer 632 and the second sublayer 634. The first sublayer 632 is disposed in the first region 110 and the third region 130, the second sublayer 634 is disposed in the second region 120 and the fourth region 140, and the separation space SP is located between the first sublayer 632 and the second sublayer 634 and extends along the first direction D1. In the present disclosure, the capacitor structure 600 is disposed in the first trenches 200, the second trenches 300, the third trenches 400 and the fourth trenches 500, and is a deep trench capacitor structure. Compared with a planar capacitor structure, the depth of each of the trenches can increase the area of the capacitor structure 600. Accordingly, a larger capacitance value can be provided.

The semiconductor device 1 may further include a plurality of first contacts CT1 and a plurality of second contacts CT2. For other details of the first contacts CT1, the second contacts CT2 and the semiconductor device 1, reference may be made to the relevant description above.

In the top view of the semiconductor device 1, the semiconductor device 1 has an area A1 in the first region 110, the first trenches 200 and the second trenches have a total trench portion area A2 in the first region 110, and the following condition may be satisfied: 20%≤A2/A1≤35%. The area A1 may be defined as the projection area of the bottom electrode layer 610 on the top surface 101 of the substrate 100 in the first region 110. The total trench portion area A2 may be defined as the sum of the areas of all the trench portions of the first trenches 200 and the second trenches 300 on the top surface 101 of the substrate 100 in the first region 110, i.e., the sum of the areas of the trench portions 210, 230, 310, 330 and 350 on the top surface 101 of the substrate 100 in the first region 110. The first trenches 200 and the second trenches 300 have a total partition portion area A3 in the first region 110, and the following condition may be satisfied: 2%≤A3/A1≤3%. The total partition portion area A3 may be defined as the sum of the areas of all the partition portions of the first trenches 200 and second trenches 300 on the top surface 101 of the substrate 100 in the first region 110, i.e., the sum of the areas of the partition portions 220, 320 and 340 on the top surface 101 of the substrate 100 in the first region 110. Similarly, the semiconductor device 1 has an area A4 in the second region 120, the third trenches 400 and the fourth trenches 500 have a total trench portion area A5 and a total partition portion area A6 in the second region 120, and the following conditions may be satisfied: 20%≤A5/A4≤35%; and 2%≤A6/A4≤3%. The semiconductor device 1 has an area A7 in the third region 130, the third trenches 400 and the fourth trenches 500 have a total trench portion area A8 and a total partition portion area A9 in the third region 130, and the following conditions may be satisfied: 20%≤A8/A7≤35%; and 2%≤A9/A7≤3%. The semiconductor device 1 has an area A10 in the fourth region 140, the third trenches 400 and the fourth trenches 500 have a total trench portion area A11 and a total partition portion area A12 in the fourth region 140, and the following conditions may be satisfied: 20%≤A11/A10≤35%; and 2%≤A12/A10≤3%. Thereby, although the trenches of the semiconductor device 1 are disposed with the partition portions, the proportion of area of the trench portions in the semiconductor device 1 is much larger than the proportion of the area of the partition portions, which is beneficial to maintain the capacitance value of the capacitor structure 600.

In this embodiment, the substrate 100 defines four regions. Thereby, the capacitor structure 600 is simultaneously disposed in the first region 110, the second region 120, the third region 130 and the fourth region 140, and the capacitor structure 600 can have a larger area, which is beneficial to increase the capacitance value. However, it is only exemplary, and the present disclosure is not limited thereto. In other embodiments, the substrate 100 may only define a region, which can also release the compressive stress perpendicular to the trench length direction. In addition, the number of the regions may also be adjusted to provide the desired capacitance value according to actual needs.

In this embodiment, the extending directions of the trenches in any two adjacent regions are different from each other, such as perpendicular to each other, which can further reduce the stress. Specifically, for the first region 110 and the second region 120 that are adjacent to each other in the second direction D2, the extending directions of the first trenches 200 and the second trenches 300 are perpendicular to the extending directions of the third trenches 400 and the fourth trenches 500. For the third region 130 and the fourth region 140 that are adjacent to each other in the second direction D2, the extending directions of the third trenches 400 and the fourth trenches 500 are perpendicular to the extending directions of the first trenches 200 and the second trenches 300. For the first region 110 and the third region 130 that are adjacent to each other in the first direction D1, the extending directions of the first trenches 200 and the second trenches 300 are perpendicular to the extending directions of the third trenches 400 and the fourth trenches 500. For the second region 120 and the fourth region 140 that are adjacent to each other in the first direction D1, the extending directions of the third trenches 400 and the fourth trench 500 are perpendicular to the extending directions of the first trenches 200 and the second trenches 300.

Compared with the arrangement that the first trenches 200 to the fourth trenches 500 all extend along the first direction D1, it is beneficial to reduce the compressive stress along the second direction D2 in this embodiment. Compared with the arrangement that the first trenches 200 to the fourth trenches 500 all extend along the second direction D2, it is beneficial to reduce the compressive stress along the first direction D1 in this embodiment.

Compared with the prior art, in the present disclosure, with a single trench being divided into at least two trench portions by a partition portion, and the partition portions of two adjacent trenches being misaligned with each other in a direction perpendicular to the trench length direction, the compressive stress can be reduced. Thereby, it is beneficial to increase the depth of the trenches. On the one hand, the requirement for a larger capacitance value provided by the capacitor structure can be satisfied. On the other hand, the yield being reduced due to excessive compressive stress caused by the larger depth of the trench may be avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate defining a first region;
a first trench disposed in the first region of the substrate and extending along a first direction, wherein the first trench comprises a first trench portion, a first partition portion and a second trench portion sequentially arranged along the first direction;
a second trench disposed in the first region of the substrate and extending along the first direction, wherein the second trench comprises a third trench portion, a second partition portion and a fourth trench portion sequentially arranged along the first direction, and the first partition portion and the second partition portion are misaligned with each other in a second direction perpendicular to the first direction; and
a capacitor structure disposed in the first trench and the second trench and on a top surface of the substrate.

2. The semiconductor device of claim 1, wherein the second trench further comprises a fifth trench portion and a third partition portion disposed between the fourth trench portion and the fifth trench portion, and the first partition portion and the third partition portion are misaligned with each other in the second direction.

3. The semiconductor device of claim 2, wherein there is a midpoint between the second partition portion and the third partition portion, and the first partition portion corresponds to the midpoint along the second direction.

4. The semiconductor device of claim 1, wherein a number of the first trenches is at least two, a number of the second trenches is at least two, and each of the at least two of the first trenches and each of the at least two of the second trenches are alternatively disposed along the second direction.

5. The semiconductor device of claim 1, wherein the substrate further defines a second region adjacent to the first region along the second direction, and the semiconductor structure further comprises:
a third trench disposed in the second region of the substrate and extending along the second direction, wherein the third trench comprises a sixth trench portion, a fourth partition portion and a seventh trench portion sequentially arranged along the second direction; and
a fourth trench disposed in the second region of the substrate and extending along the second direction, wherein the fourth trench comprises an eighth trench portion, a fifth partition portion and a ninth trench portion sequentially arranged along the second direction, and the fourth partition portion and the fifth partition portion are misaligned with each other in the first direction.

6. The semiconductor device of claim 5, wherein the substrate further defines a third region and a fourth region, the third region is adjacent to the first region along the first direction, the fourth region is adjacent to the second region along the first direction, and the semiconductor structure further comprises:
another first trench disposed in the fourth region of the substrate and extending along the first direction;
another second trench disposed in the fourth region of the substrate and extending along the first direction;
another third trench disposed in the third region of the substrate and extending along the second direction; and
another fourth trench disposed in the third region of the substrate and extending along the second direction.

7. The semiconductor device of claim 5, wherein the capacitor structure, from bottom to top, comprises:
a bottom electrode layer disposed in the first trench and the second trench and on the top surface of the substrate;
an insulating layer disposed on the bottom electrode layer; and
a top electrode layer disposed on the insulating layer, wherein the top electrode layer comprises a first sublayer and a second sublayer, the first sublayer is disposed in the first region, the second sublayer is disposed in the second region, and a separation space is formed between the first sublayer and the second sublayer and extends along the first direction.

8. The semiconductor device of claim 7, further comprising:
a plurality of first contacts arranged along the first direction, and the plurality of first contacts are electrically connected to the bottom electrode layer; and
a plurality of second contacts arranged along the second direction, and the plurality of second contacts are electrically connected to the top electrode layer.

9. The semiconductor device of claim 1, wherein the first trench has a depth and a width, and a ratio of the depth to the width is 24 to 36.

10. The semiconductor device of claim 1, wherein in a top view of the semiconductor device, the semiconductor device has an area A1 in the first region, the first trench and the second trench have a total trench portion area A2, and the following condition is satisfied: 20%≤A2/A1 35%.

11. A method for fabricating a semiconductor device, comprising:
providing a substrate defining a first region;
forming a first trench in the first region of the substrate and extending along a first direction, wherein the first trench comprises a first trench portion, a first partition portion and a second trench portion sequentially arranged along the first direction;
forming a second trench in the first region of the substrate and extending along the first direction, wherein the second trench comprises a third trench portion, a second partition portion and a fourth trench portion sequentially arranged along the first direction, and the first partition portion and the second partition portion are misaligned with each other in a second direction perpendicular to the first direction; and
forming a capacitor structure in the first trench and the second trench and on a top surface of the substrate.

12. The method of claim 11, wherein the second trench further comprises a fifth trench portion and a third partition portion disposed between the fourth trench portion and the fifth trench portion, and the first partition portion and the third partition portion are misaligned with each other in the second direction.

13. The method of claim 12, wherein there is a midpoint between the second partition portion and the third partition portion, and the first partition portion corresponds to the midpoint along the second direction.

14. The method of claim 11, wherein a number of the first trenches is at least two, a number of the second trenches is at least two, and each of the at least two of the first trenches and each of the at least two of the second trenches are alternatively disposed along the second direction.

15. The method of claim 11, wherein the substrate further defines a second region adjacent to the first region along the second direction, and the method further comprises:
forming a third trench in the second region of the substrate and extending along the second direction, wherein the third trench comprises a sixth trench portion, a fourth partition portion and a seventh trench portion sequentially arranged along the second direction; and
forming a fourth trench in the second region of the substrate and extending along the second direction, wherein the fourth trench comprises an eighth trench portion, a fifth partition portion and a ninth trench portion sequentially arranged along the second direction, and the fourth partition portion and the fifth partition portion are misaligned with each other in the first direction.

16. The method of claim 15, wherein the substrate further defines a third region and a fourth region, the third region is adjacent to the first region along the first direction, the fourth region is adjacent to the second region along the first direction, and the method further comprises:
forming another first trench in the fourth region of the substrate and extending along the first direction;
forming another second trench in the fourth region of the substrate and extending along the first direction;
forming another third trench in the third region of the substrate and extending along the second direction; and
forming another fourth trench in the third region of the substrate and extending along the second direction.

17. The method of claim 15, wherein forming the capacitor structure comprises:
forming a bottom electrode layer in the first trench and the second trench and on the top surface of the substrate;
forming an insulating layer on the bottom electrode layer;
forming a top electrode layer on the insulating layer; and
removing a portion of the top electrode layer to form a separation space, wherein the separation space extends along the first direction.

18. The method of claim 17, further comprising:
forming a plurality of first contacts arranged along the first direction, and the plurality of first contacts are electrically connected to the bottom electrode layer; and
forming a plurality of second contacts arranged along the second direction, and the plurality of second contacts are electrically connected to the top electrode layer.

19. The method of claim 11, wherein the first trench has a depth and a width, and a ratio of the depth to the width is 24 to 36.

20. The method of claim 11, wherein in a top view of the semiconductor device, the semiconductor device has an area A1 in the first region, the first trench and the second trench have a total trench portion area A2, and the following condition is satisfied: 20%≤A2/A1≤35%.
